(19) United States
(12) Patent Application Publication
(10) Pub. No.: US 2026/0002963 A1
(43) Pub. Date: Jan. 1, 2026

(54) PROBE CARD AND TEST APPARATUS

(71) Applicant: JCET STATS ChipPAC Korea Limited, Incheon (KR)

(72) Inventors: HyeonJong KIM, Incheon (KR); MoonKyu CHUN, Gyeonggi-do (KR); YoungEun SEO, Incheon (KR)

(21) Appl. No.: 19/245,450

(22) Filed: Jun. 23, 2025

(30) Foreign Application Priority Data
Jun. 26, 2024 (CN) 202410839870.1

(51) Int. Cl. G01R 1/073; G01R 31/26

(52) U.S. Cl. CPC G01R 1/07314; G01R 31/2601

(57) ABSTRACT

A probe card and a test apparatus are provided. The probe card may include: a substrate; a plurality of probes attached on the substrate and configured to contact conductive pads of a semiconductor device under test, wherein the plurality of probes includes a ground probe configured to contact a ground pad of the semiconductor device, and a signal probe configured to contact a signal pad of the semiconductor device; and at least one filter attached on the substrate, wherein the at least one filter is electrically coupled with the signal probe and configured to eliminate interference signals received from the signal probe.

### TECHNICAL FIELD

The present application generally relates to semiconductor technology, and more particularly, to a probe card and a test apparatus.

### BACKGROUND OF THE INVENTION

The semiconductor industry is constantly faced with complex integration challenges as consumers want their electronics to be smaller, faster and higher performance with more and more functionalities packed into a single device. Wafer testing is an important part of the semiconductor industry to confirm electrical parameters and functional operations of semiconductor dice. Defective dice may be identified at the wafer level and removed from the manufacturing process to avoid failures in higher level systems, for example, in multi-die packages. However, due to external or mutual interferences, it is difficult to accurately measure signals in radio frequency integrated circuits (RFICs). Therefore, a need exists for an improved test apparatus.

### SUMMARY OF THE INVENTION

An objective of the present application is to provide an improved probe card for wafer testing.

According to an aspect of the present application, a probe card is provided. The probe card may include: a substrate; a plurality of probes attached on the substrate and configured to contact conductive pads of a semiconductor device under test, wherein the plurality of probes includes a ground probe configured to contact a ground pad of the semiconductor device, and a signal probe configured to contact a signal pad of the semiconductor device; and at least one filter attached on the substrate, wherein the at least one filter is electrically coupled with the signal probe and configured to eliminate interference signals received from the signal probe.

According to another aspect of the present application, an apparatus for testing a semiconductor device is provided. The apparatus may include: a wafer stage configured for supporting the semiconductor device; a probe card including: a substrate; a plurality of 1 probes attached on the substrate and configured to contact conductive pads of a semiconductor device under test, wherein the plurality of probes includes a ground probe configured to contact a ground pad of the semiconductor device, and a signal probe configured to contact a signal pad of the semiconductor device; and at least one filter attached on the substrate, wherein the at least one filter is electrically coupled with the signal probe and configured to eliminate interference signals received from the signal probe; and a tester configured for generating a test signal input into the semiconductor device through the signal probe and/or receiving a response signal output by the semiconductor device through the signal probe.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. I illustrates a schematic diagram of a test apparatus according to an embodiment of the present application.

FIG. 2 illustrates a schematic diagram of contacts between a semiconductor device under test and a probe card according to an embodiment of the present application.

FIG. 3A is a cross-sectional view illustrating the probe card shown in FIG. 2.

FIG. 3B is an enlarged view of a portion of the probe card shown in FIG. 3A

FIG. 4A illustrates a schematic diagram of a probe card according to another embodiment of the present application.

FIG. 4B is an enlarged view of a portion of the probe card shown in FIG. 4A. The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application. In this application, the use of the singular includes the plural unless specifically stated otherwise.

In this application, the use of the singular includes the plural unless specifically stated otherwise. In this application, the use of "or" means "and/or" unless stated otherwise. Furthermore, the use of the term "including" as well as other forms such as "includes" and "included" is not limiting. In addition, terms such as "element" or "component" encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as "beneath", "below", "above", "over", "on", "upper", "lower", "left", "right", "vertical", "horizontal", "side" and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being "connected to" or "coupled to" another element, it may be directly connected to or coupled to the other element, or intervening elements may be present.

Referring to FIG. 1, a schematic diagram of a test apparatus 100 is illustrated according to an embodiment of the present application. The test apparatus 100 may include a wafer stage 110, a probe card 120 and a tester 140, and is configured for testing a semiconductor device 200 supported on the wafer stage 110.

The semiconductor device 200 may be mounted on the wafer stage 110, for example, with vacuum pressure. The wafer stage 110 may be capable of moving in the "x", "y", and "z" directions, and, in some cases, may also be capable of tilting about the "x" and "y" axes and rotating about the "z" axis. Thus, the semiconductor device 200 mounted on the wafer stage 110 can also travel in the "x", "y", and "z" directions for testing purposes. In some embodiments, the wafer stage 110 may be maneuvered so that probes 130 of the probe card 120 can electrically contact conductive pads 220 of the semiconductor device 200.

In some embodiments, an evaluation board (EVB) may be mounted on the wafer stage 110. The EVB is a hardware platform provided by a manufacturer or supplier of the semiconductor device 200 to evaluate the performance and functionality of the semiconductor device 200. The EVB may include peripheral circuits, interfaces, and components that are compatible with the semiconductor device 200. The EVB may be coupled to the semiconductor device 200 and the tester 140 to facilitate testing of semiconductor device 200.

The semiconductor device 200 may include semiconductor dice of an unsingulated semiconductor wafer, semiconductor dice singulated from a wafer (packaged or unpackaged), one or more arrays of singulated dice disposed in a carrier or other holding device, multi-die electronics modules, printed circuit boards, or any other type of electronic devices. In some embodiments, the semiconductor device 200 may be an open-top (OT) module. That is, the conductive pads 220 of the semiconductor device 200 are exposed from its top surface, such that the probes 130 of the probe card 120 can contact them directly. In some embodiments, the semiconductor device 200 may include one or more radio frequency integrated circuits (RFICs) or microwave integrated circuits. For example, the semiconductor device 200 may include an integrated circuit for wireless communication and/or signal processing, which may require antennas for transmitting and receiving wireless signals. The semiconductor device 200 may further include a transceiver having a transmitting circuit, a receiving circuit, and/or AD/DA convertors. However, the semiconductor device 200 of the present application is not limited to the above examples, and may include other devices to be tested.

The tester 140 may be configured to control testing of the semiconductor device 200. For example, the tester 140 is configured to generate test signals to be fed to the semiconductor device 200, and process response signals received from the semiconductor device 200. The test signals may include test stimuli such as commands, data, addresses of memory locations. The tester 140 may send and receive the test signals and the response signals through the probe card 120 to the conductive pads 220 of the semiconductor device 200. The tester 140 can test the electrical parameters and functional operations of the semiconductor device 200, and evaluate the response signals to determine whether the semiconductor device 200 pass the testing and/or to rate the semiconductor device 200. In some embodiments, the tester 140 may include one or more oscilloscopes, one or more computers, or an automatic test equipment (ATE).

The probe card 120 serves an electromechanical interface between the tester 140 and the semiconductor device 200. Specifically, the probe card 120 includes a plurality of probes (for example, cantilever probes or vertical probes) 130 which are used for establishing a physical (mechanical and electrical) contact with the conductive pads 220 of the semiconductor device 200. The probes 130 may extend downward from a substrate of the probe card 120, and match a geometry of the conductive pads 220 of the semiconductor device 200. In an exemplary testing process, the wafer stage 110 may align the conductive pads 220 of the semiconductor device 200 with respective probes 130 of the probe card 120, and then move the conductive pads 220 into contact with the probes 130 and thereby create electrical connections between the probes 130 and the conductive pads 220 of the semiconductor device 200.

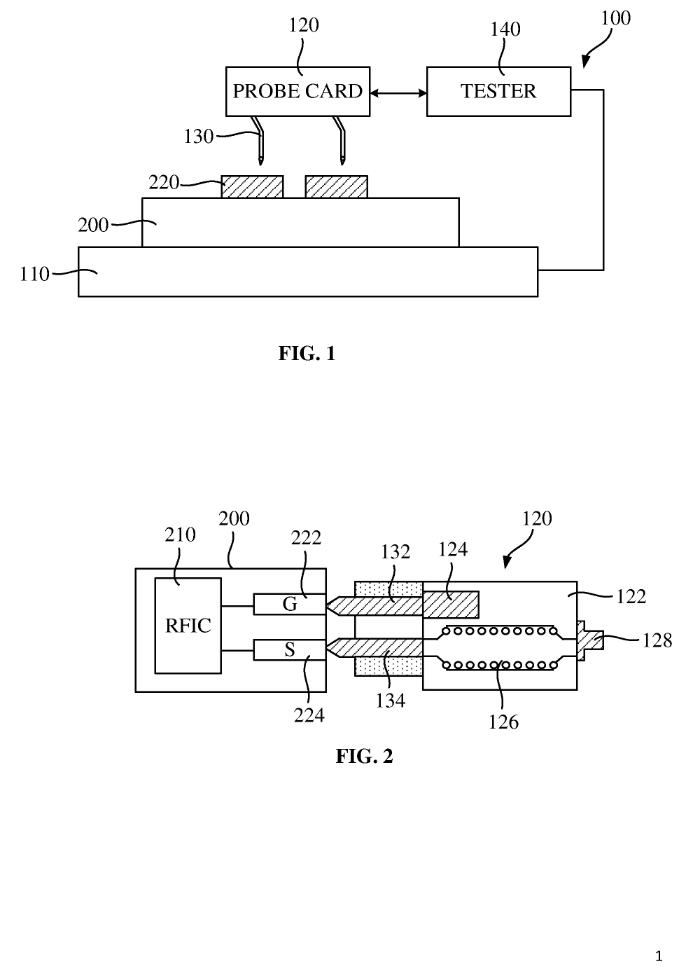

Referring to FIG. 2, a schematic diagram of the contacts between the semiconductor device 200 and the probe card 120 is illustrated according to an embodiment of the present application.

In the example shown in FIG. 2, the plurality of probes of the probe card 120 includes a ground probe 132 and a signal probe 134. The ground probe 132 is configured to contact a ground pad 222 of the semiconductor device 200, and the signal probe 134 is configured to contact a signal pad 224 of the semiconductor device 200. Both the ground pad 222 and the signal pad 224 are electrically coupled to a RFIC 210 of the semiconductor device 200. The ground probe 132 and the signal probe 134 may be resilient and conductive pins. For example, the ground probe 132 and the signal probe 134 are made of a material including or consisting of beryllium copper. However, the present application is not limited thereto, and in some other embodiments, the ground probe 132 and the signal probe 134 are made of a material including or consisting of tungsten or other metal having good electrical conductivity and resilient mechanical properties, so long as a reliable electrical connection with the ground pad 222 and the signal pad 224 of the semiconductor device 200 can be provided.

The probe card 120 include a substrate 122. In some embodiments, the substrate 122 may be a printed circuit board (PCB). However, the present application is not limited thereto. In some other examples, the substrate 122 may include a ceramic substrate, an organic substrate, a laminate interposer, a strip interposer, a leadframe, or other suitable substrates. The substrate 122 may include any structure on or in which an integrated circuit system can be fabricated or mounted. For example, the substrate 122 may include one or more insulating or passivation layers, one or more conductive vias formed through the insulating layers, and one or more conductive layers formed over or between the insulating layers.

In some embodiments, the ground probe 132 and the signal probe 134 are attached on the substrate 122 through any suitable attaching techniques well known to those of ordinary skill in the art of semiconductor fabrication. The ground probe 132 and the signal probe 134 may be electrically connected to conductive (e.g., metallic) bonding pads formed on the substrate 122. For example, the ground probe 132 is electrically connected to a grounding pad 124 which is coupled to a reference node or potential (e.g., ground).

In some embodiments, the probe card 120 may further include a space transformer (not shown) which electrically connects the probes 132 and 134 to the substrate (for example, PCB) 122. The space transformer may include, for example, a multi-layer ceramic substrate or a multi-layer organic substrate, and can provide pitch reduction, high routing density and localized mid-frequency decoupling.

The RFIC 210 may receive or output various high-frequency signals through the signal pad 224, which are susceptible to external or mutual interferences. Thus, in order to accurately measure these signals, the probe card 120 may further include at least one filter 126 configured to eliminate some or all interference signals received from the signal probe 134. The filter 126 is attached or formed on the substrate 122 and electrically coupled with the signal probe 134.

In some embodiments, the filter 126 may include a microstrip filter. An advantage of the microstrip filter is that all active components can be mounted on or formed on top of a PCB (for example, the substrate 122). The microstrip filter can be built as a carefully defined pattern on the PCB. There is less limit to the filter designs which can be built using a PCB pattern cut with hairpin curves, straight lines of varying widths, and other geometric arrangements singly or in combinations.

In some embodiments, the filter 126 may include a substrate integrated waveguide (SIW) filter. The SIW filter is new form of filter and has advantages in design of efficient circuits and components operating in the RF and microwave frequency spectrum. Microstrip components are good for low frequency applications but are not good enough at extreme frequencies and involve rigorous fabrication concessions in the implementation of RF, microwave, and millimeter-wave components. This is due to wavelengths being short at higher frequencies. Waveguide devices, on the other hand, are ideal for higher frequency systems, but are very costly, hard to fabricate, and challenging to integrate with planar components in the neighborhood. The SIW filter can connects the gap that existed between conventional waveguide and microstrip filter.

In some embodiments, the filter 126 may include a high pass filter (or low-cut filter or bass-cut filter) when a harmonics measurement is performed on the signals transmitted on the signal probe 134. In some embodiments, the filter 126 may include a band pass filter when a fundamental measurement is performed on the signals transmitted on the signal probe 134. However, the present application is not limited to the above embodiments, and in some other embodiments, the probe card 120 may include any type of filter according to actual needs.

Continuing referring to FIG. 2, the probe card 120 further includes a radio frequency connector 128 mounted on the substrate 122 and electrically coupled to the filter 126, so as to establish a communication channel between the probe card 120 and the tester 140. In some embodiments, the radio frequency connector 128 may include a "Radio Frequency connector, Subminiature, type A" (SMA) connector. The SMA connector has screw type coupling mechanism which minimizes reflections and attenuation by ensuring uniform contact, and can be used in a wide range of applications including antenna connections for most sub 6 GHz technologies like Wi-Fi and Bluetooth. However, the present application is not limited to the above embodiment, and in some other embodiments, the connector 128 may be other connectors suitable for high-frequency communication.

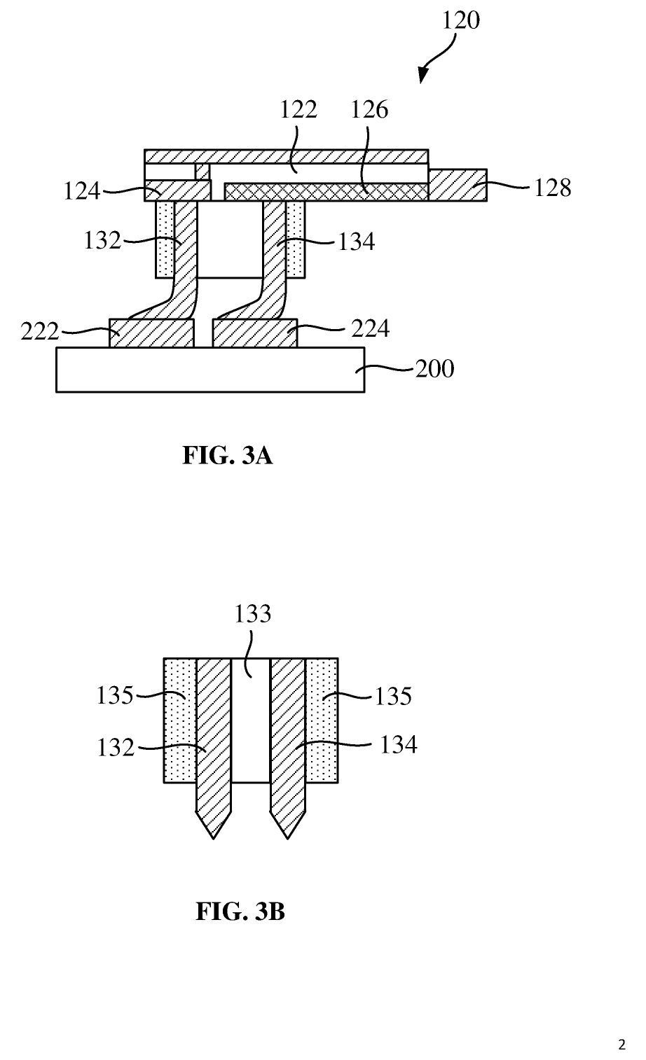

Referring to FIG. 3A and FIG. 3B, a cross-sectional view of the probe card 120 shown in FIG. 2 is illustrated, and FIG. 3B is an enlarged view of a portion of the probe card 120 shown in FIG. 3A.

Referring to FIG. 3A, the ground probe 132 and the signal probe 134 are resilient pins, and they may bend on the ground pad 222 and the signal pad 224 under a downward pressure, thereby increasing a contact area and establishing a reliable electrical connection therebetween.

Referring to FIG. 3B, the probe card 120 includes an insulating spacer 133 disposed between the ground probe 132 and the signal probe 134. The insulating spacer 133 can fix the ground probe 132 and the signal probe 134, and isolate them from each other to avoid shorting or interferences. In some embodiments, the insulating spacer 133 is made of a material including or consisting of a fluororesin. Specifically, examples of the fluororesin include polytetrafluoroethylene (PTFE), tetrafluoroethylene/perfluoro (allkylvinyl ether) copolymer (PFA), tetrafluoroethylene/hexafluoropropylene copolymer(FEP), polyethylene/tetrafluoroethylene copolymer (ETFE), polyvinylidene fluoride (PVDF), polychloro-trifluoroethylene (PCTFE), and vinyl fluoride (PVF). However, the present application is not limited to the above embodiment, and in some other embodiments, the insulating spacer 133 may include a silicone resin, a polyimide resin, or other suitable insulating material.

Moreover, the probe card 120 further includes an absorber layer 135 disposed outside the ground probe 132 and the signal probe 134 to electrically isolate the ground probe 132 and the signal probe 134 from external circumstances. The absorber layer 135 may include materials, for example, elastomer or rubber-based, that attenuate energy in an electromagnetic wave. The absorber layer 135 may take different physical forms including flexible elastomers or foam or rigid epoxy or plastics, and can reduce interference between circuit components and unwanted electromagnetic radiation from external circumstances.

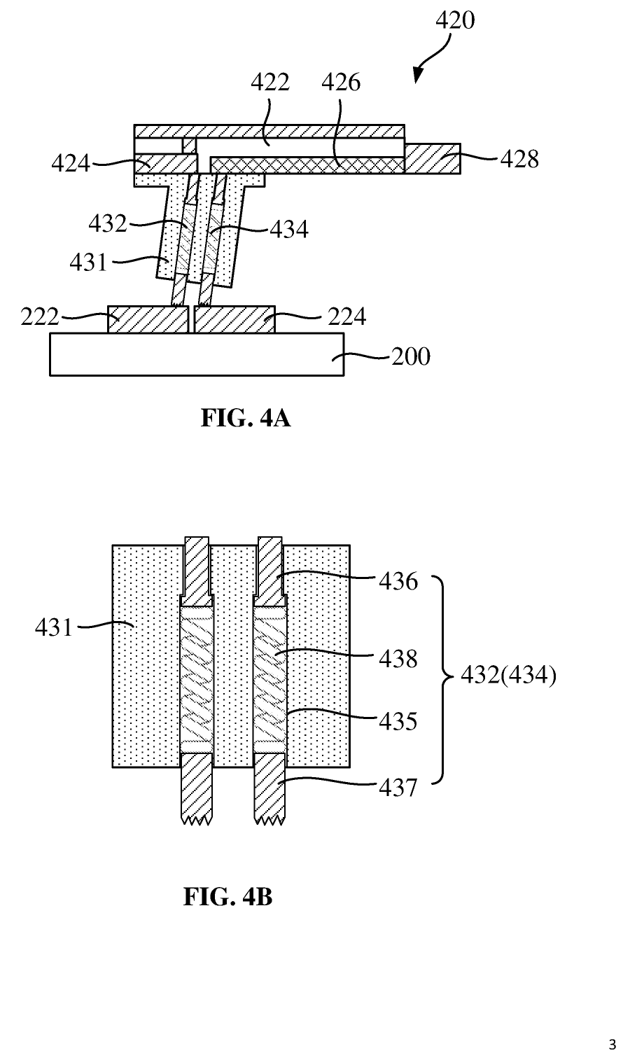

Referring to FIG. 4A and FIG. 4B, FIG. 4A illustrates a schematic diagram of a probe card 420 according to another embodiment of the present application, FIG. 4B is an enlarged view of a portion of the probe card 420 shown in FIG. 4A. The probe card 420 may have some similar structures and configurations as the probe card 120 shown in FIG. 2, FIG. 3A and FIG. 3B. The similar or same parts between the probe card 420 and the probe card 120 will not be elaborated herein.

Specifically, the probe card 420 includes a substrate 422 and a plurality of probes attached thereon, for example, a ground probe 432 and a signal probe 434. The ground probe 432 is configured to contact a ground pad 222 of the semiconductor device 200, and the signal probe 434 is configured to contact a signal pad 224 of the semiconductor device 200. The ground probe 432 is electrically connected to a grounding pad 424 on the substrate 422, and the signal probe 434 is electrically connected to a filter 426 attached or formed on the substrate 422. The probe card 420 further includes a radio frequency connector 428 mounted on the substrate 422 and electrically coupled to the filter 426, so as to establish a communication channel between the probe card 420 and a tester.

Different from the probe card 120 shown in FIG. 3B, the ground probe 432 and the signal probe 434 of the probe card 420 are Pogo pins. Specifically, as shown in FIG. 4B, at least upper portions of the Pogo pins 432 and 434 may be covered with an insulating body 431, for example, polyetheretherketone (PEEK). The Pogo pins 432 or 434 are used for electrically connecting the ground pad 222 and the signal pad 224 of the semiconductor device 200 to the probe card 420, and the insulating body 431 can fix and support the Pogo pins 432 and 434 to protect them from deformation and external physical impact.

As shown in FIG. 4B, each Pogo pin 432 or 434 includes a pipe-shaped pin body 435, a metallic top contactor 436 coupled to a top end of the pin body 435, a metallic bottom contactor 437 coupled to a bottom end of the pin body 435, and a compressible coil spring 438 disposed inside the pin body 435. The compressible coil spring 438 can contact with the top contactor 436 at its top end, and contact with the bottom contactor 437 at its bottom end. With these configurations, when the probe card 420 is used for testing the semiconductor device 200, the semiconductor device 200 can be loaded onto the wafer stage 110 as shown in FIG. 1, with the bottom contactors 437 of the Pogo pins 432 and 434 contacting with the ground pad 222 and the signal pad 224 of the semiconductor device 200. An external force can be applied onto the probe card 420, thereby the probe card 420 pressing the top contactors 436 of the Pogo pins 432 and 434. As such, the coil springs 438 can provide an elastic connection between the pads 222 and 224 of the semiconductor device 200 and the Pogo pins 432 and 434 of the probe card 420.

In an example, the pipe-shaped pin body 435, the top contactor 436 and the bottom contactor 437 are made of brass or copper, and the coil spring 438 is made of copper alloys or spring steel. However, the present application does not limit the material of the Pogo pins 432 and 434 to that disclosed herein. In the example shown in FIG. 4B, a bottom surface of the bottom contactor 437 may protrude from a bottom surface of the insulating body 431 and may have peaks and valleys, so as to facilitate contacting with the conductive pads of the semiconductor device 200. A top surface of the top contactor 436 may protrude from a top surface of the insulating body 431, so as to electrically coupled to the grounding pad 424 and the filter 426 mounted on the substrate 422. It could be understood that, the Pogo pins shown in FIG. 4B are exemplary only, and may vary according to actual needs.

The discussion herein included numerous illustrative figures that showed various portions of a probe card and a test apparatus. For illustrative clarity, such figures did not show all aspects of each example devices. Any of the example apparatuses and/or methods provided herein may share any or all characteristics with any or all other apparatuses and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A probe card, comprising:
a substrate;
a plurality of probes attached on the substrate and configured to contact conductive pads of a semiconductor device under test, wherein the plurality of probes comprises a ground probe configured to contact a ground pad of the semiconductor device, and a signal probe configured to contact a signal pad of the semiconductor device; and
at least one filter attached on the substrate, wherein the at least one filter is electrically coupled with the signal probe and configured to eliminate interference signals received from the signal probe.

2. The probe card of claim 1, wherein the at least one filter comprises a microstrip filter, or a substrate integrated waveguide (SIW) filter.

3. The probe card of claim 1, wherein the plurality of probes comprise a resilient and conductive pin.

4. The probe card of claim 3, wherein the pin is made of a material comprising or consisting of beryllium copper.

5. The probe card of claim 3, further comprising:an insulating spacer disposed between the ground probe and the signal probe; andan absorber layer disposed outside the ground probe and the signal probe to electrically isolate the ground probe and the signal probe from external circumstances.

6. The probe card of claim 5, wherein the insulating spacer is made of a material comprising or consisting of a fluororesin.

7. The probe card of claim 1, wherein the plurality of probes comprises a Pogo pin having:a pipe-shaped pin body;a top contactor coupled to a top end of the pin body;1 a bottom contactor coupled to a bottom end of the pin body; and
a compressible coil spring disposed inside the pin body and configured to contact with the top contactor at its top end and contact with the bottom contactor at its bottom end.

8. The probe card of claim 7, wherein at least a portion of the pin body is covered with a material comprising polyetheretherketone.

9. The probe card of claim 1, further comprising:a radio frequency connector mounted on the substrate and electrically coupled to the at least one filter.

10. The probe card of claim 1, wherein the substrate comprises a printed circuit board (PCB).

11. The probe card of claim 1, wherein the semiconductor device comprises a radio frequency integrated circuit or a microwave integrated circuit.

12. An apparatus for testing a semiconductor device, comprising:
a wafer stage configured for supporting the semiconductor device;
a probe card comprising:
a substrate;
a plurality of probes attached on the substrate and configured to contact conductive pads of a semiconductor device under test, wherein the plurality of probes comprises a ground probe configured to contact a ground pad of the semiconductor device, and a signal probe configured to contact a signal pad of the semiconductor device; and
at least one filter attached on the substrate, wherein the at least one filter is electrically coupled with the signal probe and configured to eliminate interference signals received from the signal probe; and
a tester configured for generating a test signal input into the semiconductor device through the signal probe and/or receiving a response signal output by the semiconductor device through the signal probe.

13. The apparatus of claim 12, wherein the at least one filter comprises a microstrip filter, or a substrate integrated waveguide (SIW) filter.

14. The apparatus of claim 12, wherein the plurality of probes comprise a resilient and conductive pin.

15. The apparatus of claim 14, wherein the pin is made of a material comprising or consisting of beryllium copper.

16. The apparatus of claim 14, wherein the probe card further comprises:an insulating spacer disposed between the ground probe and the signal probe; andan absorber layer disposed outside the ground probe and the signal probe to electrically isolate the ground probe and the signal probe from external circumstances.

17. The apparatus of claim 12, wherein the plurality of probes comprises a Pogo pin having:a pipe-shaped pin body;a top contactor coupled to a top end of the pin body;a bottom contactor coupled to a bottom end of the pin body; anda compressible coil spring disposed inside the pin body and configured to contact with the top contactor at its top end and contact with the bottom contactor at its bottom end.

18. The apparatus of claim 12, wherein the probe card further comprises:a radio frequency connector mounted on the substrate and electrically coupled to the at least one filter.

19. The apparatus of claim 12, wherein the substrate comprises a printed circuit board (PCB).

20. The apparatus of claim 12, wherein the semiconductor device comprises a radio frequency integrated circuit or a microwave integrated circuit 3.
